(19) United States
(12) Patent Application Publication
(10) Pub. No.: US 2010/0314667 A1
(43) Pub. Date: Dec. 16, 2010

(54) CMOS PIXEL WITH DUAL-ELEMENT TRANSFER GATE

(75) Inventors: Hidetoshi Nozaki, Sunnyvale, CA (US); Tiejun Dai, Santa Clara, CA (US)

Correspondence Address: BLAKELY SOKOLOFF TAYLOR & ZAFMAN LLP, 1279 Oakmead Parkway, Sunnyvale, CA, 94085-4040, US

(73) Assignee: OMNIVISION TECHNOLOGIES, INC., Santa Clara, CA (US)

(21) Appl. No.: 12/781,638

(22) Filed: May 17, 2010

Related U.S. Application Data
(60) Provisional application No. 61/186,315, filed on Jun. 11, 2009.

(51) Int. Cl. H01L 31/112; H01L 31/18

(52) U.S. Cl. 257/225; 438/60; 257/E31.073

(57) ABSTRACT

Embodiments of a pixel that includes a photosensitive region, a floating diffusion region, and a transistor transfer gate disposed between the photosensitive region and the floating diffusion region. The transfer gate includes first and second transfer gate elements, the first transfer gate element having a different doping than the second transfer gate element. By controlling the doping of the first and second transfer gate elements a transfer gate can be provided with a greater threshold voltage near the photosensitive region and a lesser threshold voltage near the floating diffusion region. Other embodiments, including process embodiments, are disclosed and claimed.

### CROSS-REFERENCE TO RELATED APPLICATIONS

This application claims priority under 35 U.S.C. §119(e) to U.S. Provisional Patent Application No. 61/186,315, filed 11 Jun. 2009 and still pending. The priority application is incorporated herein by reference in its entirety.

### TECHNICAL FIELD

The present invention relates to image sensors and in particular, but not exclusively, to dual-element transfer gates in image sensor pixel cells.

### BACKGROUND

An image sensor is fabricated using complementary metal oxide semiconductor (“CMOS”) technology or charge coupled device (“CCD”) technology. The image sensor commonly includes several pixels (“pixels”). A typical pixel includes a microlens, a color filter, a photosensitive region, a floating diffusion region, and transistors for reading out a signal from the photosensitive region. One of the transistors is a transfer transistor. The transfer transistor has a transfer gate disposed between the photosensitive region and the floating diffusion. The transfer gate is disposed on a gate oxide. The photosensitive region, floating diffusion region, and gate oxide are supported on a substrate.

A typical pixel operates as follows. Light is incident on the microlens, which focuses the light to the photosensitive region through the color filter. The photosensitive region detects the light and converts the light into an electrical signal proportional to the intensity of the light detected. The transfer gate transfers the electrical signal from the photosensitive region to the floating diffusion region.

FIG. 1 shows a cross-sectional view of a portion of a pixel 100 of a front side illuminated (“FSI”) CMOS image sensor (“CIS”) including a conventional transfer gate structure. The front side of exemplary pixel 100 is a side of substrate 120 upon which pixel circuitry and a metal stack 105 for redistributing signals are formed. Metal stack 105 includes first and second metal layers, M1 and M2, respectively, which are patterned to allow light (indicated by dashed arrows 106) incident on pixel 100 and refracted by microlens 108 to reach a photosensitive region 110. Pixel 100 further includes a color filter 112 disposed under microlens 108. A substrate 120 supports photosensitive region 110, a p-type pinning layer 116 over the photosensitive region 110, a floating diffusion (“FD”) region 125 disposed in a P well 130, and a shallow trench isolation (“STI”) 135. A transfer gate 140 of a transfer transistor (not fully illustrated) is disposed between photosensitive region 110 and FD region 125, and is used to transfer the signal output by photosensitive region 110 to FD region 125. A conducting channel 143 is formed under the transfer gate when a bias voltage is applied to the transfer gate. The bias voltage at which the channel forms is called the threshold voltage (Vt) and is largely defined by an ion-implanted region, indicated in FIG. 1 as Vt implant region 145. Generally, an image sensor includes several pixels 100 arranged in an array of two dimensional rows and columns supported on substrate 102.

Pixel 100 operates as follows. During an integration period (also referred to as an exposure or accumulation period), light is incident on photosensitive region 110. Photosensitive region 110 generates an electrical signal in response to the incident light. The electrical signal is held in photosensitive region 110. At this stage, the transfer transistor may be turned off. If the bias voltage on the transfer gate 140 is a negative voltage, or when the bias voltage on transfer gate 140 is less than its threshold voltage, the channel region 143 between photosensitive region 110 and FD region 125 effectively becomes resistant to electron flow. A driving force is created that tends to hinder electron motion from photosensitive region 110 to FD region 125.

After the integration period, transfer gate 140 is turned on to read out the signal from photosensitive region 110. For example, a positive bias voltage is applied to transfer gate 140. When the bias voltage on transfer gate 140 is increased, the portion of channel region 143 near FD region 125 first becomes conductive. Channel region 143 continues to gradually become conductive toward photosensitive region 110 as the threshold voltage is approached. The potential in channel region 143 is dependent on the doping concentration at each point, as well as on the transfer-gate-to-substrate metal-semiconductor contact potential difference or work function difference. In transfer gate 140 of FIG. 1, the metal-semiconductor contact potential difference is uniform across channel region 143 between photosensitive region 110 and FD region 125. Also, in channel region 143 of transfer gate 140, the potential gradually decreases from photosensitive region 110 toward FD region 125, thus generating a lateral electric field that aids the transfer of charge from photosensitive region 110 to FD region 125. After the electrical signal in photosensitive region 110 has been transferred to FD region 125, transfer gate 140 is turned off in anticipation of the next integration period.

### BRIEF DESCRIPTION OF THE DRAWINGS

Non-limiting and non-exhaustive embodiments of the present invention are described with reference to the following figures, wherein like reference numerals refer to like parts throughout the various views unless otherwise specified.

FIG. 1 is a cross-sectional view of a portion of a pixel including a conventional transfer gate structure.

FIG. 2 is a side view of a portion of a pixel including a transfer gate, according to an embodiment.

FIG. 3 is a top view of a portion of a pixel including a transfer gate, according to an alternative embodiment.

FIGS. 4-9 are side views illustrating an embodiment of a process to fabricate a transfer gate, according to an embodiment.

FIGS. 10-14 are side views illustrating various alternate embodiments of a transfer gate.

FIG. 15 is a block diagram of an embodiment of an imaging system including a pixel array including a pixel according to the present invention.

### DETAILED DESCRIPTION OF THE ILLUSTRATED EMBODIMENTS

Embodiments of an apparatus, method and system for a CMOS image sensor with a dual-element transfer gate are described herein. In the following description, numerous specific details are described to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail but are nonetheless encompassed within the scope of the invention.

Reference throughout this specification to “one embodiment” or “an embodiment” means that a particular feature, structure, or characteristic described in connection with the embodiment is included in at least one embodiment of the present invention. Thus, appearances of the phrases “in one embodiment” or “in an embodiment” in this specification do not necessarily all refer to the same embodiment. Furthermore, the particular features, structures, or characteristics may be combined in any suitable manner in one or more embodiments.

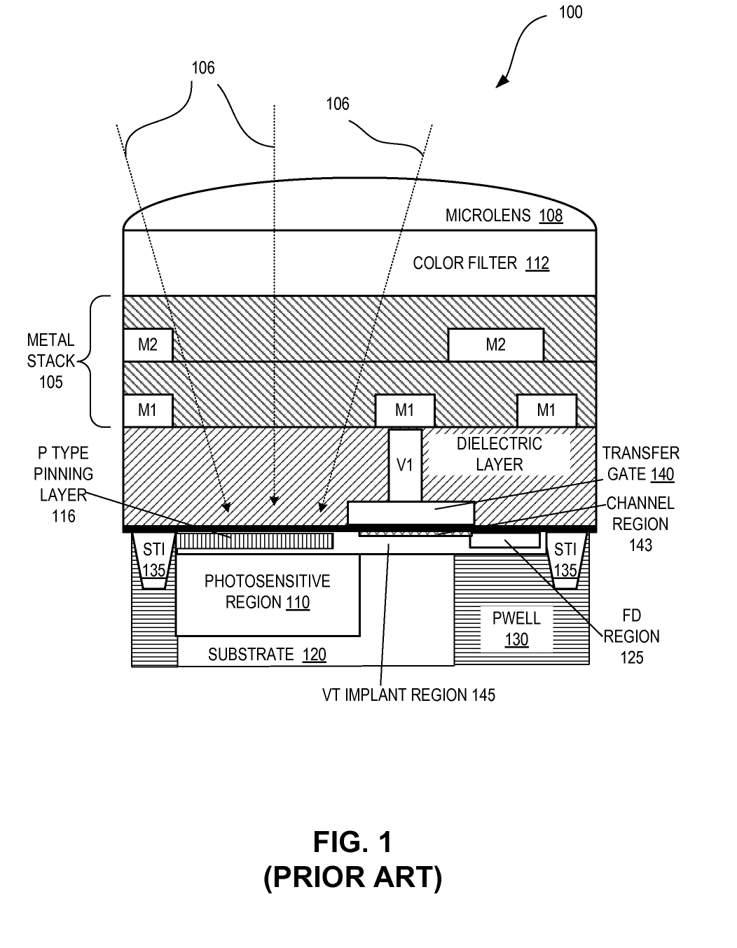

Conventional image sensor pixels, such as pixel 100 of FIG. 1, work well but have some limitations. One limitation is that photosensitive region 110 may not be completely emptied between successive readings. That is, some of the information (e.g., charge) from the previous light signal may remain in photosensitive region 110, having not been transferred to FD region 125. The leftover information is often termed image lag, residual image, ghosting, or frame-to-frame retention.

Another limitation is that photosensitive region 110 may not be able to accommodate all the charge converted from high intensity portions of an image and it may spill that excess charge into adjacent photosensitive regions. The excess charge may also spill through channel region 143 into FD region 125 before the beginning of the intended transfer period. This effect is called blooming and it limits imager dynamic range and as a result may limit the types of commercial applications of an image sensor.

One method of dealing with image lag and blooming is to employ, as a starting point, a uniform dopant underneath transfer gate 140. This approach is typical for transfer transistors using zero applied volts on their gate during collection of the electrical signal during the exposure or accumulation period. These typical transfer transistors are fabricated in part by ion-implanting a p-type dopant uniformly just below transistor channel region 143 in order to set a near-zero threshold voltage. In FIG. 1, this ion implantation region is shown as a Vt implant region 145. In addition to the uniform threshold implant, a more heavily doped p-type region may be implanted were the transfer gate overlaps the photodiode (not shown in FIG. 1). This combination creates a stepwise-graded p-type doping region under transfer gate 140 and within channel region 143. A lateral electric field is created by means of the graded p-type doping of channel region 143 between photosensitive region 110 and FD region 125, which accelerates the electrons in channel region 143 during readout. In addition, during the photo accumulation period when the transfer transistor is held below its threshold voltage at zero volts or a small negative voltage, the lateral electric field may direct and remove excess charge from the photodiode, if it should saturate, and thereby reduce blooming. Yet another action of the lateral electric field is to direct dark current generated under the transfer gate away from photosensitive region 110, thus preventing the dark current from being added to the accumulated charge in photosensitive region 110.

However, this method may lead to at least three potential problems. One potential problem is a reduction in full well capacity of photosensitive region 110 due to the diffusion of the additional p-type dopant into the photosensitive region. If the additional p-type dopant is diffused into photosensitive region 110, the n-type dopants in photosensitive region 110 may be compensated and the amount of charge an individual photosensitive region 110 can hold before saturating may be reduced. A second potential problem is the formation of a potential energy barrier at the region where photosensitive region 110 connects to channel region 143 underneath transfer gate 140. Consequently, not all the photo-generated electrons are able to leave photosensitive region 110 during readout since some are not energetic enough to cross this potential energy barrier. A third potential problem is that, although the zero volt threshold of the transfer gate tends to help direct charge out of photosensitive region 110 during moderate blooming, the associated typical channel p-type doping level is too high and more severe blooming may not be accommodated. The excess signal charge can overflow into adjacent photodiodes. There is need for an improved transfer gate structure that maximizes photosensitive region full well capacity while preventing blooming and image lag.

The conventional transfer gate often suffers from image lag and blooming. This problem may be due to the fact that conventional channel doping structures are doped such that a potential barrier remains under the transfer gate near the photosensitive region and a residual signal charge is prevented from being transferred. That is, the greater the potential barrier, the less charge will be transferred to the floating diffusion region. This potential barrier may be influenced by the characteristics of the pixel cell including, but not limited to: (1) dopant levels in the channel region of the transfer gate; (2) dopant levels in the transfer gate channel region used to adjust the threshold voltage; (3) transfer gate oxide thickness; (4) p-type pinning layer dopant levels; (5) photosensitive region dopant levels; and (6) any background substrate dopant concentration. One conventional pixel cell will incorporate within a p-type substrate an n-type photosensitive region with p-type pinning layer. The transfer gate will be doped with n-type dopant and the FD region will be formed by an n-type dopant within a p-type well. Conventional methods to reduce this potential barrier have resulted in degraded sub-threshold leakage current for the transfer gate and degraded dark current characteristics. It is difficult to optimize both potential barrier and sub-threshold leakage current and dark current generation characteristics for the transfer gate in CMOS image sensors. What is needed is a technique for manufacturing a CMOS pixel cell having both a reduced potential barrier in an area where a photosensitive region and a transfer gate structure are in close proximity to one another and also with low sub-threshold leakage characteristics.

Embodiments described in this disclosure address the problems described above and provide a method of forming a pixel cell and the resultant pixel cell. According to an embodiment, an image sensor includes an array of pixels disposed in a substrate. An individual pixel includes a photosensitive region and a floating diffusion (“FD”) region. A transfer gate with gate oxide having a uniform thickness is disposed between the photosensitive region and the FD region. The FD region is contained within a p-type well that extends underneath the transfer gate. The conventional threshold implant is absent from the transistor channel region. For ease of fabrication it may simply retain the doping concentration of the starting p-type epitaxial (epi) substrate. The transfer gate structure disposed between the photosensitive region and the FD region may be composed of two elements. This transfer gate structure may be a single polysilicon gate structure with two separately-doped adjacent regions or two separate but adjacent polysilicon gate structures with different doping occupying the same space as the single polysilicon gate structure.

The transfer transistor gate comprises at least one gate element region having a metal-semiconductor contact potential difference of a p-type polysilicon gate over a p-type silicon substrate and a second gate element region having a metal-semiconductor contact potential difference of an n-type polysilicon gate over a p-type silicon substrate. Tailoring the gate element region metal-semiconductor contact potential difference using alternative doping characteristics for the at least one gate element region allows the transfer transistor gate and its operation to be modulated and optimized. Specifically, a desired threshold voltage may be achieved with reduced or omitted channel doping, thereby helping to reduce a potential barrier in the region where a photosensitive region and transfer transistor gate are in close proximity to one another and to simultaneously provide superior sub-threshold leakage characteristics and dark current characteristics. This disclosure exploits the approximately one-volt difference in the metal-semiconductor contact potential difference between transfer gate elements fabricated from n-type polysilicon and p-type polysilicon to create a lateral electric field under the transfer transistor gate elements.

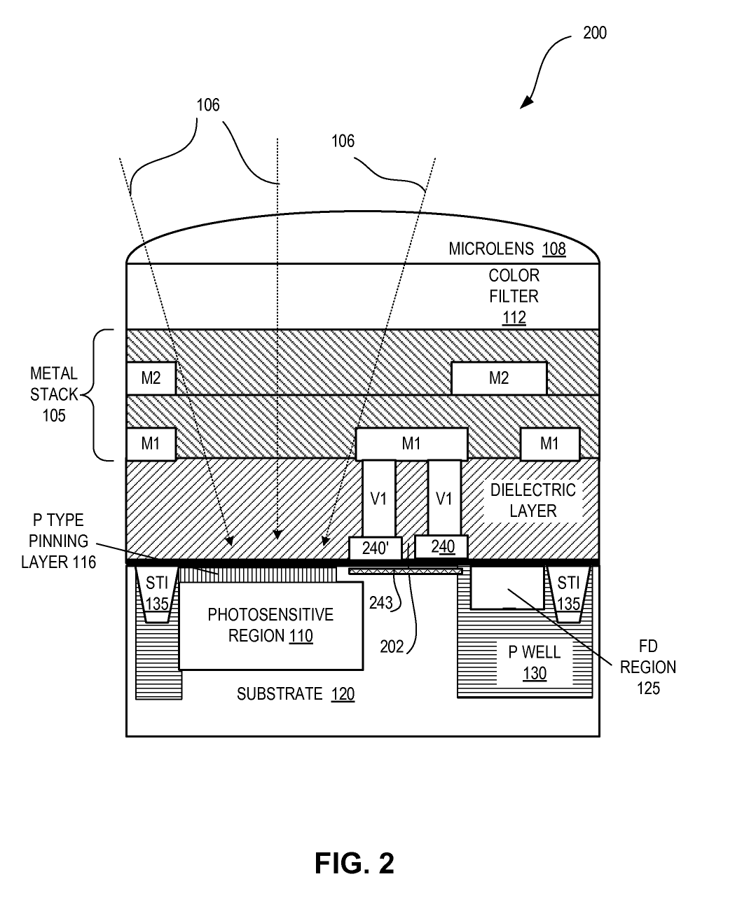

FIG. 2 illustrates a side view of a portion of a pixel 200 of a front side illuminated CMOS image sensor including a transfer gate structure, according to an embodiment. In the illustrated embodiment, pixel 200 includes structures similar to pixel 100. The transfer gate structure of pixel 200 differs from that of pixel 100 primarily in that two transfer gate elements 240′ and 240 are shown. Gate element 240 can be n-doped while gate element 240′ can be p-doped. This way, the Vt implant region 145 may be absent or have a reduced level compared to pixel 100. There is a region between transfer gate element 240 and second transfer gate element 240′ referred to as a gap 202. Transfer gate element 240 and second transfer gate element 240′ are electrically interconnected via M1 and share the same bias voltage. However, due to the approximately one volt difference in the gate-metal-to-semiconductor contact potentials between the p-doped and n-doped polysilicon gate elements, the surface potential varies laterally within transfer transistor channel region 243. With a given bias on the transfer gate elements 240 and 240′ and an appropriately designed width for gap 202 between transfer gates 240 and 240′, the channel potential will increase from the region where photosensitive region 110 overlaps the p-doped transfer gate element 240′ to where FD region 125 overlaps the n-doped transfer gate element 240. This sloping potential gradient results in an electric field that causes signal charge to transfer efficiently. Combined with the low channel doping near photosensitive region 110, this structure allows for high full well capacity and low image lag. In particular this structure may reduce signal-dependent image lag as well.

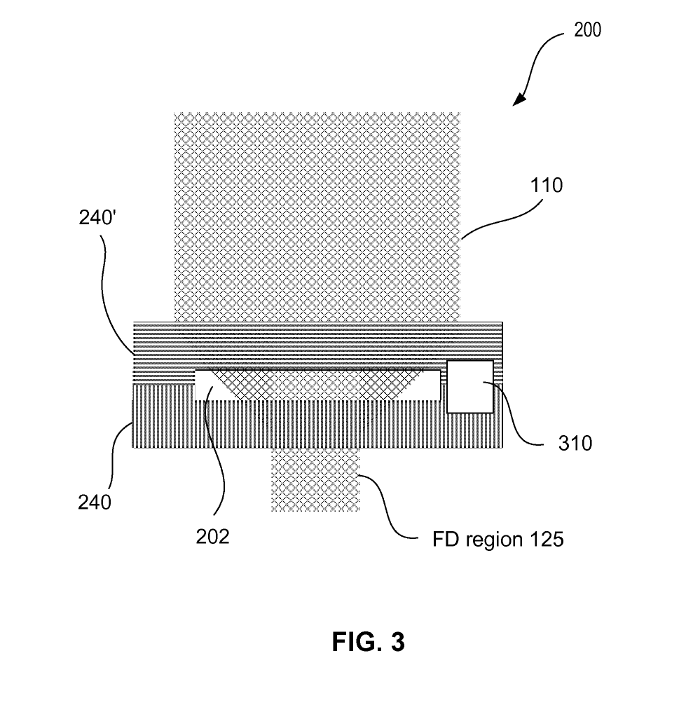

FIG. 3 is a top view of a portion of pixel 200 including a dual element transfer gate, in accordance with an embodiment. Two oppositely doped transfer gates 240 and 240′ are separated by gap 202. Also in this embodiment the two transfer gates may be conveniently electrically interconnected and jointly connected to a metal interconnect through contact region 310, connected with layer M1 of metal stack 105 shown in FIG. 2.

The width of gap 202 influences the signal transfer between photosensitive region 110 and FD region 125. Beyond a certain gap width, a potential barrier may be formed in substrate 120 between first transfer gate element 240 and second transfer gate element 240′, which may degrade signal charge transfer. For example, gap widths of 0.3 μm or less provide suitable signal charge transfer characteristics. Substrate doping and the level of Vt implant doping may also affect the choice of operable gap widths.

In some cases, there may be benefits of the dual element transfer gate structure that may remain even in the absence of a gap between elements. For example, a part of a single transfer gate structure may be doped with p-type dopants while the remaining portion of the transfer gate structure may be doped with n-type dopants. The dopants within the transfer gate structure may be abutting each other, or diffused into each other so as to slightly overlap, or remain separated by small distance with an effect similar to as if the aforedescribed gap width distance were specifically included.

The presence of the p-type doped gate element has a further benefit in regard to dark current generation. In the conventional case where the p-type silicon substrate has an n-type doped transfer gate the channel region surface is depleted, enhancing the generation-recombination (“g-r”) process via surface states. That is, surface states continually trap and release electrons into the channel region and can add to signal noise. The presence of the p-type doped transfer gate element (i.e., second transfer gate element 240′) may cause holes to be attracted to the surface of the channel region under the p-type doped gate element and thereby neutralize the dark current generating surface states.

Embodiments described herein may be formed using industry-standard fabrication techniques used to fabricate CMOS image sensors. Photolithography, ion implantation, chemical vapor deposition (“CVD”), and etching are among standard industry practices used to fabricate CMOS image sensors.

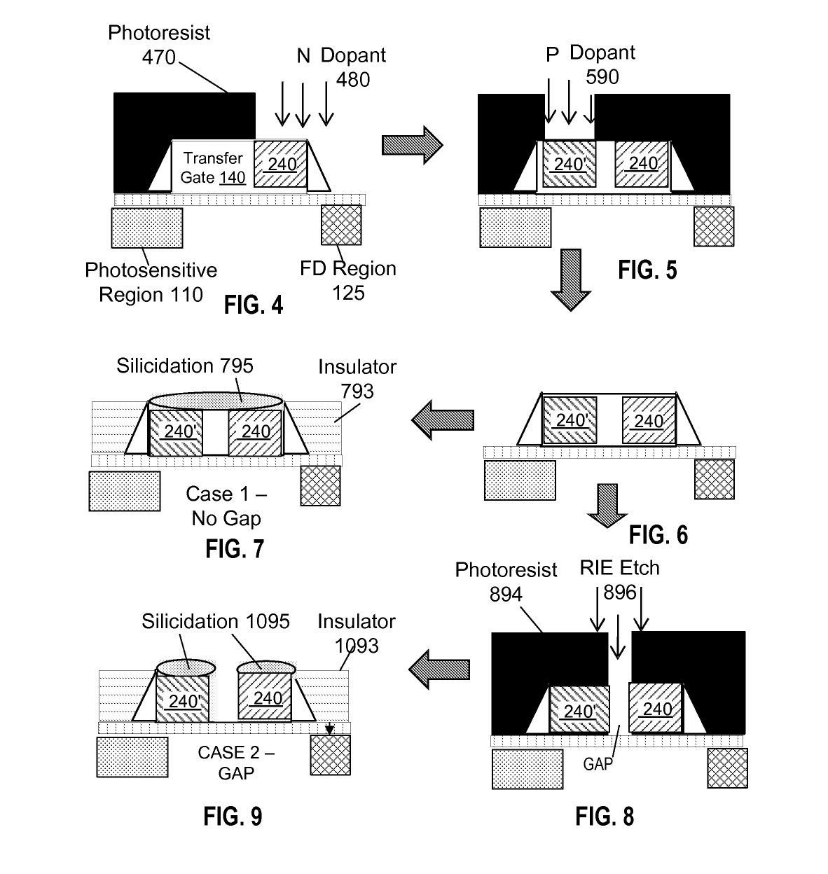

FIGS. 4-9 show variations of a method for forming the dual-element transfer gate embodiment as illustrated in FIG. 2. For example, the n-type doped polysilicon gate element 240 may be formed by ion implantation of a n-type dopant within a photoresist mask designated portion of transfer gate 140, as shown in FIG. 4. A following step may form p-type doped polysilicon gate element 240′ by ion implantation of a p-type dopant within a photoresist mask designated portion of transfer gate 140, as shown in FIG. 5. The photoresist mask is removed, as shown in FIG. 6. At least two possible variant structures may then be formed from this point. FIG. 7 shows a first case (“Case 1”) wherein the dual element gate comprised of gate element 240′ and gate element 240 is covered with deposited insulator 793 and then insulator 793 is removed from the top of gate element 240′ and gate element 240 and then gate element 240′ and gate element 240 have a silicide 795 or metal formed thereon. In this case, the dual element gate is one structure with two oppositely doped regions which are electrically connected by the silicide or metal covering.

In an alternate embodiment shown in FIG. 8, a photoresist mask 894 and RIE etch process 896 create a physical gap between the oppositely doped elements of the transfer gate. The transfer gate elements 240′ and 240 are covered with a deposited insulator 1093 and then insulator 1093 is removed from the top of transfer gate elements 240′ and 240 and then gate element 240′ and gate element 240 have a silicide 1095 or metal formed thereon, as shown in FIG. 9.

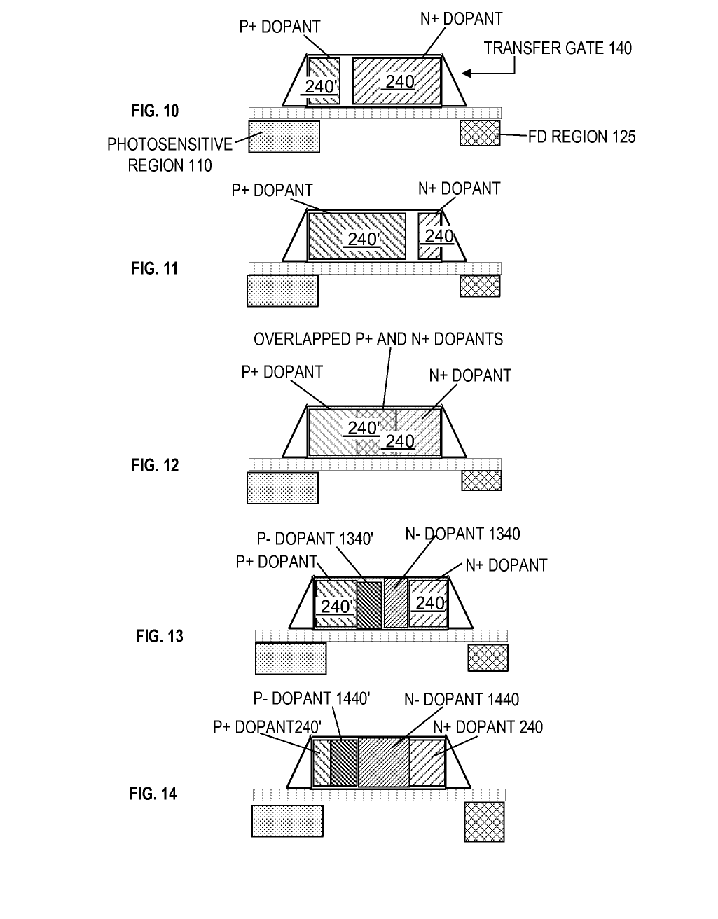

Although in the illustrated embodiment both transfer gate elements have substantially the same dimensions, in other embodiments the two transfer gate elements need not have equal dimensions. The p-type doped gate element may constitute only a fraction of total length of the transfer gate with the remaining gate length doped with n-type dopant. FIGS. 10-14 show alternative embodiments where the transfer gate element widths are varied. FIG. 10 shows a transfer gate wherein p-type doped gate element 240′ is smaller than n-type doped gate element 240. FIG. 11 shows a transfer gate wherein the p-type doped gate element 240′ is larger than the n-type doped gate element 240. FIG. 12 shows a transfer gate wherein p-type doped gate element 240′ and n-type doped gate element 240 are overlapped. FIG. 13 shows a transfer gate wherein p-type gate element 240′ and n-type gate element 240 are separated by more lightly doped p-type gate element 1340′ and more lightly doped n-type gate element 1340. FIG. 14 shows a transfer gate wherein the four regions shown in FIG. 13 have arbitrary widths and may be determined at the pixel designer's discretion.

The doping concentrations and the dopant species used with the dual element transfer gate embodiments described above may be those used in the normal course of fabricating CMOS image sensors, for example from 1017 dopant atoms/cm3 to 1020 dopant atoms/cm3. Convenient p-type dopant concentrations may be those used to implant PMOS logic transistor source and drains. Convenient more lightly doped p-type dopant concentrations may be those used to implant PMOS logic transistor lightly doped drains (PLDD). Convenient n-type dopant concentrations may be those used to implant NMOS logic transistor source and drains. Convenient more lightly doped n-type dopant concentrations may be those used to implant NMOS logic transistor lightly doped drains (NLDD). Commonly used silicides and refractory metals may be employed on top of the described transfer gate elements to electrically interconnect them.

Although the above pixel embodiments have been described with reference to the formation of a p-type doped channel region and n-type photosensitive region, the embodiments described herein may also be applicable to other pixel constructions, such as a pixel with an n-type channel region and a p-type photosensitive region, with appropriate changes to the dopant and conductivity type of all structures.

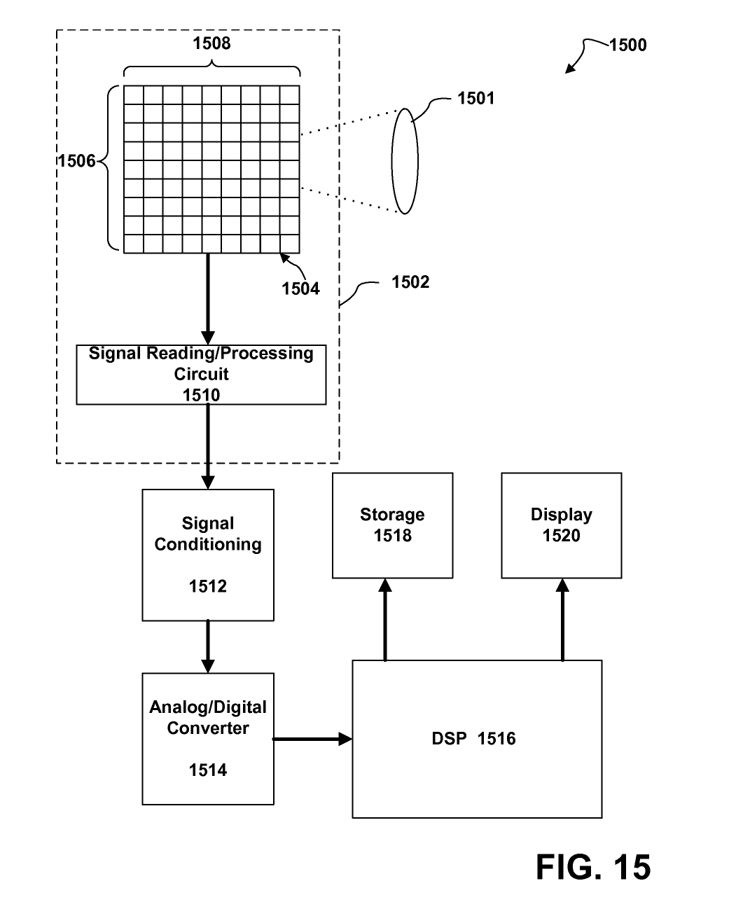

FIG. 15 illustrates an embodiment of an imaging system 1500. Optics 1501, which can include refractive, diffractive or reflective optics or combinations of these, are coupled to image sensor 1502 to focus an image onto the pixels in pixel array 1504 of the image sensor. Pixel array 1504 captures the image and the remainder of imaging system 1500 processes the pixel data from the image.

Image sensor 1502 comprises a pixel array 1504 and a signal reading and processing circuit 1510. The pixels in pixel array 1504 can be frontside-illuminated or backside-illuminated pixels and can include pixels with one or more of the transfer gate embodiments shown in FIGS. 2, 3, 7, 9 and 10-14. During operation of pixel array 1504 to capture an image, each pixel in pixel array 1504 captures incident light (i.e., photons) during a certain exposure period and converts the collected photons into an electrical charge. The electrical charge generated by each pixel can be read out as an analog signal, and a characteristic of the analog signal such as its charge, voltage or current will be representative of the intensity of light that was incident on the pixel during the exposure period.

In one embodiment pixel array 1504 is two-dimensional and includes a plurality of pixels arranged in rows 1506 and columns 1508. Illustrated pixel array 1504 is regularly shaped, but in other embodiments the array can have a regular or irregular arrangement different than shown and can include more or less pixels, rows, and columns than shown. Moreover, in different embodiments pixel array 1504 can be a gray scale image sensor, a color image sensor including red, green, and blue pixels or magenta, cyan and yellow pixels, or an image sensor that operates in the non-visible portions of the spectrum such as infrared or ultraviolet.

Image sensor 1502 includes signal reading and processing circuit 1510. Among other things, circuit 1510 can include circuitry and logic that methodically reads analog signals from each pixel, filters these signals, corrects for defective pixels, and so forth. In an embodiment where circuit 1510 performs only some reading and processing functions, the remainder of the functions can be performed by one or more other components such as signal conditioner 1512 or DSP 1516. Although shown in the drawing as an element separate from pixel array 1504, in some embodiments reading and processing circuit 1510 can be integrated with pixel array 1504 on the same substrate or can comprise circuitry and logic embedded within the pixel array. In other embodiments, however, reading and processing circuit 1510 can be an element external to pixel array 1504 as shown in the drawing. In still other embodiments, reading and processing circuit 1510 can be an element not only external to pixel array 1504, but also external to image sensor 1502.

Signal conditioner 1512 is coupled to image sensor 1502 to receive and condition analog signals received from pixel array 1504 and reading and processing circuit 1510. In different embodiments, signal conditioner 1512 can include various components for conditioning analog signals. Examples of components that can be found in signal conditioner 1512 include filters, amplifiers, offset circuits, automatic gain control, etc. In an embodiment where signal conditioner 1512 includes only some of these elements and performs only some conditioning functions, the remaining functions can be performed by one or more other components such as reading and processing circuit 1510 or DSP 1516. Analog-to-digital converter (ADC) 1514 is coupled to signal conditioner 1512 to receive conditioned analog signals corresponding to each pixel in pixel array 1504 from signal conditioner 1512 and convert these analog signals into digital values.

Digital signal processor (DSP) 1516 is coupled to analog-to-digital converter 1514 to receive digitized pixel data from ADC 1514 and process the digital data to produce a final digital image. DSP 1516 can include a processor and an internal memory in which it can store and retrieve data. After the image is processed by DSP 1516, it can be output to one or both of a storage unit 1518, such as a flash memory or an optical or magnetic storage unit, and a display unit 1520 such as an liquid crystal display (LCD) or cathode ray tube (CRT) screen.

The above description of illustrated embodiments of the invention, including what is described in the abstract, is not intended to be exhaustive or to limit the invention to the precise embodiments disclosed. While specific embodiments of, and examples for, the invention are described herein for illustrative purposes, various equivalent modifications are possible within the scope of the invention, as those skilled in the relevant art will recognize. These modifications can be made to the invention in light of the above detailed description.

The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

1. A pixel comprising:
a photosensitive region disposed in a substrate;
a floating diffusion region disposed in the substrate;
a transistor channel region disposed in the substrate between the photosensitive region and the floating diffusion region; and
a transfer gate disposed over an insulator over the transistor channel region, the transfer gate including at least first and second transfer gate elements, the first transfer gate element having a different doping than the second transfer gate element.

2. The pixel of claim 1 wherein the first transfer gate element is doped with a different dopant type than the second transfer gate element.

3. The pixel of claim 2 wherein the first transfer gate element has p-type doping and the second transfer gate element has n-type doping.

4. The pixel of claim 1 wherein the first transfer gate element has a different dopant concentration than the second transfer gate element.

5. The pixel of claim 1 wherein the first transfer gate element is closest to the photosensitive region and has p-type doping and the second transfer gate element is closest to the floating diffusion and has n-type doping.

6. The pixel of claim 1 wherein the first and second transfer gate elements are physically separate structures separated by a gap.

7. The pixel of claim 1 wherein the first and second transfer gate elements abut each other.

8. The pixel of claim 1 wherein the first and second transfer gate elements are separate regions within a single structure.

9. The pixel of claim 8 wherein the first and second regions diffuse into each other such that they overlap.

10. The pixel of claim 8 wherein the first and second regions are proximate but not abutting.

11. The pixel of claim 10 wherein the first and second regions are separated from each other by at least one additional region that is doped differently than the first region or the second region.

12. The pixel of claim 1 wherein the first transfer gate element has substantially the same dimensions as the second transfer gate element.

13. The pixel of claim 1 wherein the first transfer gate element has at least one dimension different than the second transfer gate element.

14. The pixel of claim 1 wherein the first and second transfer gate elements share the same bias voltage.

15. The pixel of claim 1 wherein the first and second transfer gate elements further comprise a metal or silicide layer formed thereon.

16. A process comprising:
forming a photosensitive region and a floating diffusion in a substrate, the photosensitive region separated from the floating diffusion by a transistor channel; and
forming a transfer gate over the transistor channel, the transfer gate including at least first and second transfer gate elements, the first transfer gate element having a different doping than the second transfer gate element.

17. The process of claim 16 wherein the first transfer gate element is doped with a different dopant type than the second transfer gate element.

18. The process of claim 17 wherein the first transfer gate element has p-type doping and the second transfer gate element has n-type doping.

19. The process of claim 16 wherein the first transfer gate element has a different dopant concentration than the second transfer gate element.

20. The process of claim 16, further comprising etching a gap between the first and second transfer gate elements so that the first and second transfer gate elements are physically separate structures.

21. The process of claim 16 wherein the first and second transfer gate elements are separate regions within a single structure.

22. The process of claim 21, further comprising diffusing the first and second regions into each other such that they overlap.

23. The process of claim 21, further comprising forming at least one additional region between the first and second regions, wherein the at least one additional region is doped differently than the first region or the second region.
